(19) United States
(12) Patent Application Publication
(10) Pub. No.: US 2009/0274835 A1
(43) Pub. Date: Nov. 5, 2009

(54) DIFFUSER/SHUTTER DESIGN FOR VAPOR PHASE LUBRICATION PROCESS

(75) Inventors: Xiaoding Ma, Fremont, CA (US); Michael Joseph Stirniman, Fremont, CA (US); John S. Bujak, San Jose, CA (US); Jing Gui, Fremont, CA (US)

Correspondence Address: Shumaker & Sieffert, P.A., 1625 Radio Drive, Suite 300, Woodbury, MN, 55125, US

(73) Assignee: Seagate Technology LLC, Scotts Valley, CA (US)

(21) Appl. No.: 12/113,347

(22) Filed: May 1, 2008

(51) Int. Cl. B05D 5/00; C23C 16/00; C23C 16/46; C23C 16/458

(52) U.S. Cl. 427/127; 118/715; 118/724; 118/728

(57) ABSTRACT

This invention relates to an apparatus for vapor lubrication comprising a chamber, a diffuser plate having an array of orifices, a shutter plate having substantially the same pattern of orifices as that of the diffuser plate, a holder for holding an object to be vapor coated in the chamber, and an actuator to move the shutter plate to align the array of orifices of the shutter plate with the array of orifices of the diffuser plate or at least partially block the array of orifices of the diffuser plate with the diffuser plate.

### BACKGROUND

Magnetic discs with magnetizable media are used for data storage in most all computer systems. Current magnetic hard disc drives operate with the read-write heads only a few nanometers above the disc surface and at rather high speeds, typically a few meters per second. Because the read-write heads can contact the disc surface during operation, a layer of lubricant is coated on the disc surface to reduce wear and friction.

FIG. 1 shows a disk recording medium and a cross section of a disc showing the difference between longitudinal and perpendicular recording. Even though FIG. 1 shows one side of the non-magnetic disk, magnetic recording layers are sputter deposited on both sides of the non-magnetic aluminum substrate of FIG. 1. Also, even though FIG. 1 shows an aluminum substrate, other embodiments include a substrate made of glass, glass-ceramic, NiP/aluminum, metal alloys, plastic/polymer material, ceramic, glass-polymer, composite materials or other non-magnetic materials.

Generally, the lubricant is applied to the disc surface by dipping the disc in a bath containing the lubricant. The bath typically contains the lubricant and a coating solvent to improve the coating characteristics of the lubricant, which is usually viscous oil. The discs are removed from the bath, and the solvent is allowed to evaporate, leaving a layer of lubricant on the disc surface.

The lubricant film on hard discs provides protection to the underlying magnetic alloy by preventing wear of the carbon overcoat. In addition, it works in combination with the overcoat to provide protection against corrosion of the underlying magnetic alloy.

In vapor phase lubrication process, the lube vapor was generated in the vacuum by heating the lube to a certain temperature and then the lubricant vapor was condensed onto discs with carbon overcoat. Deposition rate was controlled by liquid lubricant heater temperature. Comparing to traditional dip-coat lubrication process, vapor phase lubrication by lubricant evaporation has certain advantages, such as solvent-free process, uniform lube thickness without the lube feature associated with dip-lube process, etc. However, there is one disadvantage for current vapor lubrication process. In current design, the lube reservoir was heated to vaporize the lube. The lube vapor is continuously diffused out through a diffusion plate all the time even though there is no disc. Since the total lube deposition time is shorter than the idle time and transport time, the quite amount of lube was not deposited on the discs. Therefore, the lube usage would be very high comparing to the conventional dip-lube process. This invention solves the above mentioned problem in the prior art vapor lubrication apparatus for deposition of lubricant on magnetic recording media.

### SUMMARY OF THE INVENTION

The invention relates a process and an apparatus for deposition of lubricant film on storage medium using a shutter at the diffuser plate. The shutter will be open preferably only when there is a disk presented. An embodiment of the invention relates to an apparatus for vapor lubrication of a magnetic recording medium comprising a chamber, a diffuser plate having an array of orifices, a shutter and an actuator to move the shutter to open or close the orifices of the diffuser plate. These and various other features and advantages will be apparent from a reading of the following detailed description.

### BRIEF DESCRIPTION OF THE DRAWINGS

The present invention will be better understood by reference to the Detailed Description of the Invention when taken together with the attached drawings, wherein:

FIG. 1 shows a magnetic recording medium.

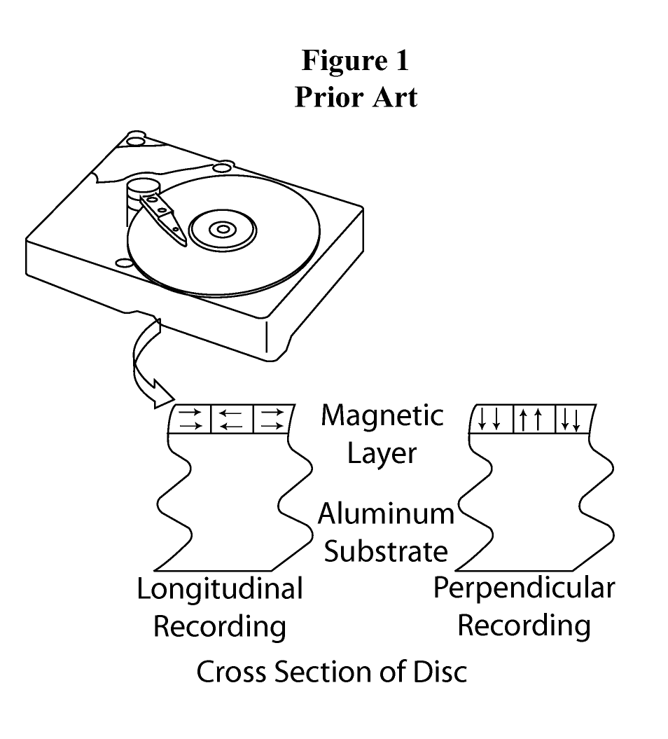

FIG. 2 shows an inline process for manufacturing magnetic recording media.

FIG. 3(a) shows a schematic of an apparatus for deposition of lubricant film on storage medium using diffuser/shutter design wherein the diffuser plate has a circular array of orifices. FIG. 3(b) shows a schematic of an apparatus for deposition of lubricant film on storage medium using diffuser/shutter design wherein the diffuser plate has a rectangular array of orifices.

FIG. 4 shows vapor lube process with (top) shutter closed; and (bottom) shutter opened.

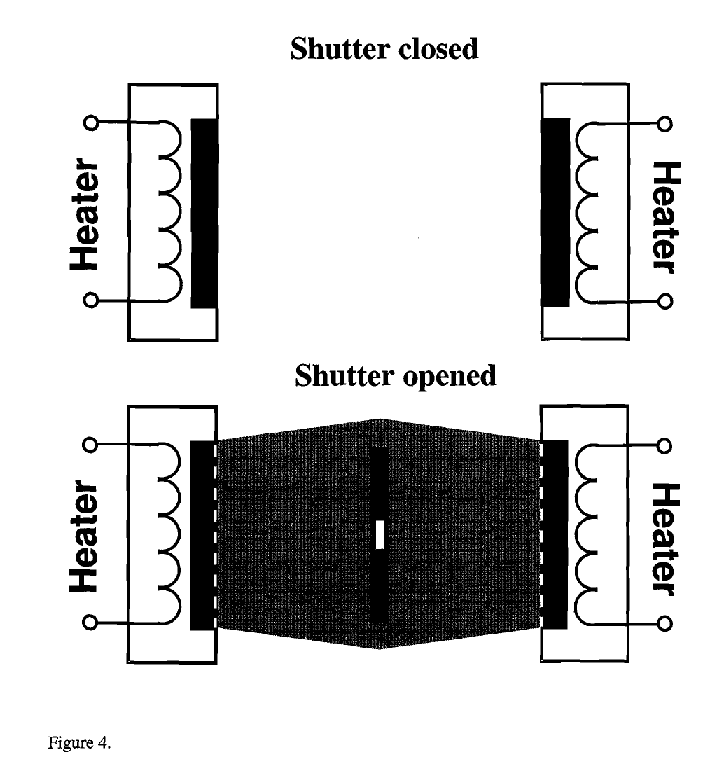

### DETAILED DESCRIPTION OF THE INVENTION

The present invention relates to an equipment and method for deposition of lubricant film on storage medium using diffuser/shutter design and, thereby, creating an effective vapor lubrication apparatus that prevents wastage of lubricant.

The invention is directed to a method of coating a substrate, particularly recording media (recording discs), with a lubricant, which is also referred in the specification to as a “lube.” Lubricants typically contain molecular weight components that range from several hundred Daltons to several thousand Daltons.

One of the approaches to improve medium corrosion resistance is vapor lube process, in which the lubricant is deposited on the medium under vacuum condition right after deposition of carbon overcoat. This approach is based on the idea that corrosion is retarded if the medium is protected by lubricant before being exposed to the atmospheric environment. The vapor lube process includes vapor deposition of perfluoropolyether (PFPE) lubricants on a medium. In this process, the lubricant is vaporized by evaporation of PFPE lubricants at elevated temperature. During the course of this invention, the inventors recognized some problems associated with the thermal evaporation process.

First, the thermal vaporization is dependent on the molecular weight of the lubricant. Lower molecule weight lubricant molecules have higher vapor pressure and evaporate faster than lubricants of higher molecular weight. This difference in the evaporation rate causes a continuous drift of the lubricant molecular weight of the lubricant deposited on a medium over a process time. Moreover, a constant deposition rate was found to be hard to maintain, and the vaporization temperature had to be raised continuously with processing time. In addition, since the lube bath was maintained at an elevated temperature, thermal degradation of the lube could occur over a period of time.

Second, thermal vapor lubing of multiple-component lubricant system was found to be difficult. Nowadays, lubricant additives, such as Bis(4-fluorophenoxy)-tetrakis(3-trifluoromethyl phenoxy) cyclotriphosphazene (XIP), are widely used to improve tribological performance of film media. Such a multiple component system would require multiple vapor lube stations to deposit the lubricant(s) and additive(s) sequentially. Yet, the thickness of each component layer was difficult to control.

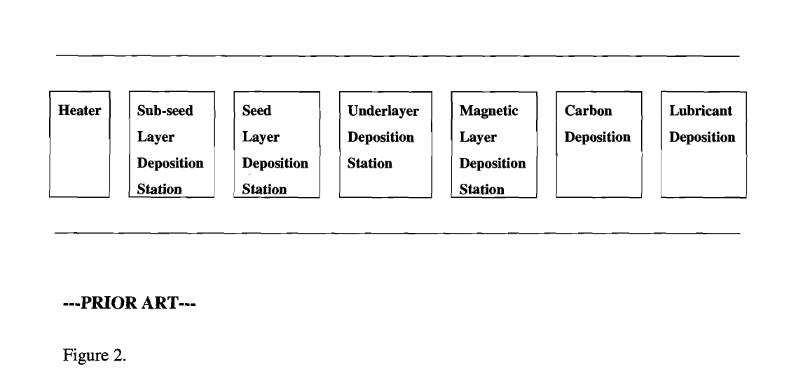

An inline process for manufacturing magnetic recording media is schematically illustrated in FIG. 2. The media substrates travel sequentially from the heater to a sub-seed layer deposition station and a sub-seed layer is formed on the media substrates. Then, the media substrates travel to a seed layer station for deposition of the seed layer, typically NiAl. Subsequent to the deposition of the sub-seed layer and the seed layer, the media substrates are passed through the underlayer deposition station wherein the underlayer is deposited. The media are then passed to the magnetic layer deposition station and then to the protective carbon overcoat deposition station. Finally, the media are passed through a lubricant layer deposition station.

Almost all the manufacturing of a disk media takes place in clean rooms where the amount of dust in the atmosphere is kept very low, and is strictly controlled and monitored. After one or more cleaning processes on a non-magnetic substrate, the substrate has an ultra-clean surface and is ready for the deposition of layers of magnetic media on the substrate. The apparatus for depositing all the layers needed for such media could be a static sputter system or a pass-by system, where all the layers except the lubricant are deposited sequentially inside a suitable vacuum environment.

Each of the layers constituting magnetic recording media of the present invention, except for a carbon overcoat and a lubricant topcoat layer, may be deposited or otherwise formed by any suitable physical vapor deposition technique (PVD), e.g., sputtering, or by a combination of PVD techniques, i.e., sputtering, vacuum evaporation, etc., with sputtering being preferred. The carbon overcoat is typically deposited with sputtering or ion beam deposition. The lubricant layer is typically provided as a topcoat by dipping of the medium into a bath containing a solution of the lubricant compound, followed by removal of excess liquid, as by wiping, or by a vapor lube deposition method in a vacuum environment.

Sputtering is perhaps the most important step in the whole process of creating recording media. There are two types of sputtering: pass-by sputtering and static sputtering. In pass-by sputtering, disks are passed inside a vacuum chamber, where they are deposited with the magnetic and non-magnetic materials that are deposited as one or more layers on the substrate when the disks are moving. Static sputtering uses smaller machines, and each disk is picked up and deposited individually when the disks are not moving. The layers on the disk of the embodiment of this invention were deposited by static sputtering in a sputter machine.

The sputtered layers are deposited in what are called bombs, which are loaded onto the sputtering machine. The bombs are vacuum chambers with targets on either side. The substrate is lifted into the bomb and is deposited with the sputtered material.

A layer of lube is preferably applied to the carbon surface as one of the topcoat layers on the disk.

Sputtering leads to some particulates formation on the post sputter disks. These particulates need to be removed to ensure that they do not lead to the scratching between the head and substrate. Once a layer of lube is applied, the substrates move to the buffing stage, where the substrate is polished while it preferentially spins around a spindle. The disk is wiped and a clean lube is evenly applied on the surface.

Subsequently, in some cases, the disk is prepared and tested for quality thorough a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the disk.

The invention involves vapor deposition of lubricant and lubricant additives on thin film medium. A lubricant solution containing lubricant(s) and lubricant additive(s), such as X-1p, is vaporized by heating or sprayed into ultra-fine droplets as small as a few microns or submicron in diameter through a nozzle into a process chamber, typically under vacuum. Optionally, there may be baffles between the media and the vacuum chamber or such baffles could be incorporated within the vacuum chamber.

In the deposition process using nozzle atomization of this invention, the low boiling point lubricant solvent in the droplets, such as Vertrel Xf, evaporates rapidly under vacuum. The fast evaporation of lubricant solvent breaks down the droplets quickly, and thus vaporizes or atomizes the PFPE lubricant in the process chamber completely. A substantially uniform deposition of the lubricant(s) and lubricant additive(s) on medium surface can be achieved thereafter. The term “atomization” refers to the breaking down of a liquid into droplets that can be suspended in a gas. The phrase “substantially uniform” means that the variation in the concentration of the lubricant from one point of an object coated with the lubricant to another point of the same object is less than 10 percent.

The lubricant(s) reaches its vapor pressure after atomization. The collision rate of lubricant molecules on a surface, S, follows a relation: S=P/2πmkT, where P and m are the vapor pressure and molecular weight of a PFPE lubricant, respectively. For a Zdol PFPE of a molecular weight of 2000 amu, its vapor pressure is about 2×10⁻⁵ Torr at 20° C. It takes about 0.32 sec to deposit a 10 Å lubricant film on medium surface. Thus, the deposition of the lubricant(s) and the additive(s) could be completed within 5 seconds an magnetic recording medium, more preferably within 1 second, exposure of the medium surface to the vapor of the lubricant(s) and additive(s).

On the other hand, idle time could be several seconds for the magnetic recording to be inserted and removed from the deposition chamber. Therefore, if the diffuser plate is maintained to be constantly open, the lube wastage would be very high.

Even though the lube deposition chamber is often called a “vacuum chamber,” which is the preferred embodiment, the lube deposition chamber does not necessarily have to be under a vacuum. The pressure of the gaseous environment in the lube deposition chamber should be such that the apparatus of this invention produces vapor or droplets of the liquid entering the nozzle such that at least a portion of the droplets can be suspended in the gaseous environment of the chamber.

If vapor lube atomization is practice, then the advantages of the atomization vapor lube process are the following. No heating is required, so that there is no thermal degradation of lube over time. The composition of lube deposited on disks is substantially the same as that in the solution. Therefore, it can deposit multiple composition at the same time in the same chamber. Since the lube is deposited at room temperature, there is no need to control the lube bath temperature. The parameter to control the deposition rate is the vacuum pressure, which can be easily set at a constant level. In general, the design of this invention addresses all the problems encountered in a thermal vaporization system.

In one variation, the medium could be irradiated with UV before or during the exposure of the medium to the vapor in the atomization chamber. The UV exposure could result in an increase in bonded lube thickness. The inventors have found that the amount of C—O and C═O bonds on carbon surface increases after UV exposure, which suggests that the ozone generated during the UV irradiation process reacts with the carbon surface to form functional groups such as COOH and C—OH. The strong dipole-dipole interaction between carboxyl and hydroxyl end groups bonded lube to the carbon surface is thus formed.

The embodiments of the invention could include an off line vacuum system that is separate from the metal and carbon in-line system, and which could preferably only do sequential vacuum deposition of lubricant followed by vacuum UV cure, followed by vent and unload.

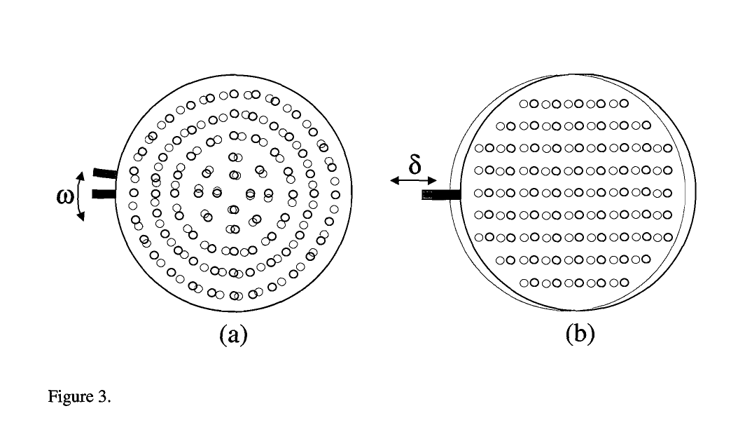

For example, the embodiments of the invention relate to a stand-alone vapor lubrication system that is separate from the sputter system. Hard disks are first coated with all the metal layers and a carbon overcoat, and then come out of the sputter machine vacuum as in the conventional sputter process. The post-sputter disks are loaded into a stand-alone vapor lubrication system to be coated with a thin layer of lubricant (referred as ex-situ vapor lubrication). The stand-alone vapor lubrication system can consist of a pre-lubricant surface treatment chamber (for example sputter etching or UV/ozone cleaning), a vapor lubrication chamber, and a post-lubrication process chamber (for example UV cure), in any combination. An example of one configuration is shown in FIG. 3.

Ultraviolet (UV) light has been widely used in the disk drive industry to increase the chemical interactions between media lubricants and media carbon overcoats. These increased interactions are generally described by the widely used but chemically imprecise industry term “bonded lubricant.” By this terminology, the bonded lubricant fraction refers to the percentage of the total lubricant film that remains on the carbon overcoat after some standardized solvent wash procedure. After the UV exposure of a lubricant film, the fractional amount of the total lubricant that is bonded is typically seen to increase, sometimes dramatically. The amount of increase depends on a number of factors, including the UV exposure time, the UV power density at the disk surface, the UV wavelength, the lubricant type and initial thickness, and the exposure environmental conditions such as temperature and oxygen partial pressure. The oxygen partial pressure is considered to be a particularly relevant parameter, due to the ability of UV photons with sufficiently high energy to break the O₂ bond and create the corrosive gas ozone during the cure process.

UV curing could be done by using mercury discharge lamps. The UV process depends strongly on the UV photon energy. In the case of the mercury discharge UV lamp, it generates only a small fraction (<15%) of its total output at the useful wavelength of 185 nm with a photon energy of 6.7 eV, with the main fraction of the power being consumed at the less useful 254 nm wavelength with a photon energy of 4.9 eV.

Xenon excimer UV lamp produces UV light at the useful wavelength of 172 nm with a photon energy of 7.2 eV. At this high energy, the 172 nm UV photon has energy high enough to break many chemical bonds. While not being limited by description on how the Xenon excimer UV lamp works, it is believed that excitation of Xenon atoms (Xe) by electrons form excited Xenon atoms (Xe*). The excited Xe* atoms react in a three body collision to form an Xe₂* excimer complex which radiates at 172 nm. This excimer system can be pumped at very high power densities (>1 MW/cm²) and is not subjected to self-absorption because the excimer has no stable ground state.

Preferably, the vapor deposition on the media and the subsequent exposure of the media to the excimer UV lamp could be done in the same chamber, and furthermore preferably without moving the media between the steps of the vapor deposition and UV exposure from the excimer UV lamp.

In the embodiments of the invention, the same chamber for both vapor deposition and UV exposure of the lubricant could be as follows. Embodiments of the present invention comprise suspending a magnetic recording medium in a deposition chamber and providing a lubricant in a source chamber as in U.S. Pat. Nos. 6,214,410, and 6,183,831, which are incorporated herein by reference. The deposition and source chambers can be constructed of any material which will function at sub-atmospheric pressures and does not interfere with the deposition process, and does not adversely affect the desired properties of the resulting product, e.g. glass, ceramic or metal. Å vacuum source could be employed to evacuate the deposition and source chambers to a pressure below atmospheric pressure, e.g. a pressure less than about 760 Torr. The temperature of the lubricant in the source chamber, i.e., the chamber which is the source of the lubricant supplied to the deposition chamber, could be then elevated above the temperature of the magnetic recording medium in the deposition chamber, which elevated temperature causes vaporized lubricant in the source chamber to flow from the source chamber to the deposition chamber and condense on a surface of the magnetic recording medium to form a lubricant topcoat. After sufficient time has elapsed to deposit a topcoat having a substantially uniform thickness substantially completely covering the surface of the recording medium, the deposition chamber can be vented to the atmosphere, or vented with a desired gas. The magnetic recording medium could then be UV treated in the same deposition chamber, and finally removed.

In accordance with embodiments of the present invention, the deposition and source chambers can be evacuated substantially concurrently to substantially the same relative pressure of about 100 Torr to about 10⁻¹⁰ Torr. After evacuating the deposition and source chambers to the desired pressure, the source chamber can be isolated from the deposition chamber and the vacuum source employing a conventional valve. Subsequent heating of the lubricant in the source chamber causes the pressure in the source chamber to increase relative to the pressure in the deposition chamber. By then opening the valve, lubricant vapor in the source chamber will flow from the source chamber to the deposition chamber. Since the deposition chamber is at a lower temperature and pressure, the heated lubricant from the source chamber deposits on the magnetic recording medium within the deposition chamber. The valve is opened for a period of time sufficient to deposit the lubricant topcoat at a desired uniform thickness. Thereafter, the valve is closed, the deposition chamber vented, the recording medium removed and the method steps repeated.

In an embodiment of the present invention, the vacuum source can be isolated from the apparatus employing another valve positioned between the vacuum source and the apparatus. By closing such a valve, the vacuum source can be isolated from the deposition chamber prior to exposing the magnetic recording medium to lubricant vapor in the deposition chamber. Practical considerations may require application of the vacuum to the deposition chamber during which the lubricant is heated in the source chamber and to ensure an adequate pressure differential between the two chambers. An embodiment of the present invention includes the use of a valve between the deposition chamber and the vacuum source.

According to the present invention, it is understood that the deposition of a lubricant topcoat on a surface of a magnetic recording medium at sub-atmospheric pressure yields improved control over the deposited topcoat layer. The amount, quality and molecular weight of the lubricant vapor which flows from the source chamber to the deposition chamber is dependent upon the relative pressure difference and the relative temperature difference between the two chambers.

It is particularly effective to reduce the pressure in the deposition chamber to within the range of about 10 Torr to about 10⁻¹⁰ Torr, e.g., within the range of about 10⁻³ Torr to about 10⁻⁹ Torr. Further, by elevating the temperature of the lubricant in the source chamber, the pressure of the source chamber is increased relative to the deposition chamber. Embodiments of the present invention include elevating the temperature of the lubricant in the source chamber to greater than about 35° C. but less than about 300° C., e.g., a temperature within the range of about 120° C. to about 220° C. By elevating the temperature of the lubricant in the source chamber, the pressure in the source chamber is also elevated. Embodiments of the present invention include evacuating the source chamber to a pressure of about 700 Torr to about 10⁻⁵ Torr, e.g., about 100 Torr to about 0.01 Torr

Irradiation of media could be achieved through the use of an irradiation apparatus comprising the deposition chamber. In such an irradiation process, discs could placed on a saddle and lifted individually into a space between two ultraviolet lamps in a dedicated process chamber.

To be of practical use, the UV cure process requires vacuum compatible UV lamps that output high enough power at high enough photon energy to effect curing in times on the order of 10 seconds or less. Excimer UV lamps output a single high-energy wavelength (e.g., 172 nm) at power densities of about 50 mW/cm², with an energy conversion efficiency of around 40%. This compares to the typical total power output of 20⁻³⁰ mW/cm² from a mercury discharge lamp, only 3⁻⁵ mW/cm or less of which is at the useful wavelength of 185 nm, and which operate at much lower conversion efficiencies. The excimer lamp can also be manufactured with vacuum compatible components, which is difficult to achieve with mercury discharge lamps. Excimer lamps use environmentally benign xenon as the working gas, eliminating the hazards associated with mercury. Finally, excimer lamps run considerably cooler than mercury discharge lamps, and no external cooling is required.

Operating the excimer lamp in vacuum simultaneously eliminates both the need for nitrogen purge and the generation of ozone during the process. If on the other hand ozone is in fact found to be of benefit, it could be incorporated into the process in a controlled manner by back filling the deposition chamber with oxygen. The UV process in conjunction with vapor deposition of lubricant eliminates the need for external UV curing tools and their associated floor space and handling steps. The vacuum process using the excimer lamp is additionally more efficient than the UV process using the mercury discharge lamp as it eliminates the attenuation of the UV power by ambient nitrogen. Unlike mercury discharge lamps, which require long warm-up times and need to be run continuously to maintain a steady output, excimer lamps require less than 1 second warm up time to reach full power, and thus can be turned on and off as part of the process.

The lubricant moieties include polyfluoroether compositions that may be terminally functionalized with polar groups, such as hydroxyl, carboxy, or amino. The polar groups provide a means of better attaching or sticking the lubricant onto the surface of the recording media. These fluorinated oils are commercially available under such trade names as Fomblin Z®, Fomblin Z-Dol®, Fomblin Ztetraol®, Fomblin Am2001®, Fomblin Z-DISOC® (Montedison); Demnum® (Daikin) and Krytox® (Dupont).

The chemical structures of some of the Fomblin lubricants are shown below.

X—CF₂—[(OCF₂—CF₂)ₘ—(OCF₂)ₙ]—OCF₂—X
Fomblin Z: Non-reactive end groups

X═F
Fomblin Zdol: Reactive end groups

X═CH₂—OH
Fomblin AM2001: Reactive end groups

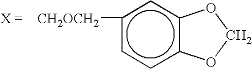

Fomblin Ztetraol: Reactive end groups

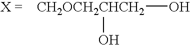

X1p is the most widely used lubricant additive for thin film storage medium. X-1P is available from the Dow Chemical Company. It has the formula:

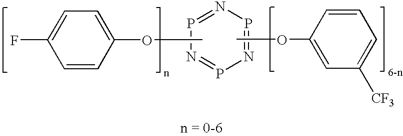

DOW Chemicals X-1p (cyclotriphosphazene lubricant)

The most remarkable benefit from X1p application is the significant improvement of durability of storage medium. However, the durability benefit of X1p could be accompanied by potential problems, such as X1p phrase separation, head smear and lubricant pickup due to the limited miscibility of X1p in PFPE lubricant. Chemically linking lubricant molecules, such as Zdol, to the cyclotriphosphazene moiety could eliminate the low miscibility problems between lubricant and X1p. However, UV light could activate X1p very effectively. The fluorophenol and trifluoromethylphenol substituents on the cyclotriphosphazene ring in X1p could be excited readily by UV exposure. A sequence of photochemical reactions could be triggered, involving shedding of the fluorophenol and trifluoromethylphenol substituents from the cyclotriphosphazene ring.

The additive moieties that could be added to the lubricant moieties in this invention include X1-p and its derivatives. Also, adding a UV curable end group to the main lubricant further dramatically decreases the time to saturation. For example, the following UV curable compounds work with Z-DOL: acrylate, methacrylate, styrene, a-methyl styrene and vinyl ester.

The UV curable end group may be added to Z-DOL by reacting it with Acrylic chloride in the following reaction:

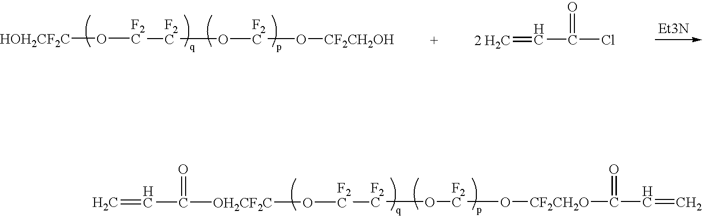

In addition to an acrylate functional group, other polymerizable functional groups including methacrylate, vinyl ester and 4-vinylbenzylate can also serve the purpose of providing a UV-curable functional end group. Those of ordinary skill may vary the particular ultraviolet wavelengths and UV-curable end groups according to the specific application which includes lubricant other than Z-DOL without varying from the scope of the invention as defined in the appended claims.

The thickness of the lubricant coating should be at least 0.5 nm, preferably at least 1 nm, and more preferably at least 1.2 nm and will generally be below 3 nm, preferably in the range from 1 nm to 3 nm. Molecular weight components of particular interest that provide higher film thickness range from 1 kD to 10 kD, preferably from 2 kD to 8 kD. Preferably, no solvent is used in the atomization apparatus of this invention. The additives could by X1P and other additives for lubricants.

The thickness of the lubricant coating should be at least 0.1 nm, preferably at least 0.7 nm, and more preferably at least 1.2 nm and will generally be below 3 nm, preferably in the range from 1 nm to 3 nm. Molecular weight components of particular interest that provide higher film thickness range from 1 kD to 10 kD, preferably from 2 kD to 8 kD.

One way of describing a distribution of molecular components of a polymer, i.e., polydispersity, is to compare the weight average molecular weight defined as

M_{w}=ΣmᵢMᵢ/Σmᵢ

where mᵢ is the total mass of molecular component in the polymer having a molecular weight Mᵢ, with the number average molecular weight defined as

Mₙ=ΣNᵢMᵢ/ΣNᵢ

where Nᵢ is the total number of each molecular component in the polymer having a molecular weight Mᵢ. The weight average molecular weight (M_{w}) of a polymer will always be greater than the number average molecular weight (Mₙ), because the later counts the contribution of molecules in each class Mᵢ and the former weighs their contribution in terms of their mass. Thus, those molecular components having a high molecular weight contribute more to the average when mass rather than number is used as the weighing factor.

For all polydisperse polymers the ratio M_{w}/Mₙ is always greater than one, and the amount by which this ratio deviates from one is a measure of the polydispersity of the polymer. The larger the M_{w}/Mₙ ratio the greater the breadth of the molecular weight distribution of the polymer.

The molecular weight distribution of the vapor phase can be sampled by condensation of the vapor onto a suitable surface, followed by analysis of the condensate in a calibrated size exclusion chromatography system.

It is desirable that the fresh lubricant has a relatively narrow molecular weight distribution of molecular components. In practice, the narrower the distribution the easier it will be to maintain a steady-state concentration of one or more components in the vapor. For example, if the highest and lowest molecular weight components in the polymer have very similar molecular weights, their vapor pressures will also be very similar. On the other hand, if the molecular weights (vapor pressures) are dramatically different heating of the lubricant will require much greater temperature and process control for a steady state concentration to be maintained. The lubricant used in the invention should have an M_{w}/Mₙ ratio between 1 and 1.6, preferably between 1 and 1.3, more preferably between 1 and 1.2.

The invention can be practiced with any commercial lubricant with a relatively large or small polydispersity, or with a lubricant that has been pre-fractionated to obtain a lubricant with a relatively small polydispersity. The preferred embodiment of the invention does not involve pre-fractionation of the lubricant. However, pre-fractionated lubricants may be used to provide relatively narrow molecular weight lubricant. If a pre-fractionated lubricant is used in the invention, distillation, chromatography, extraction, or other techniques that allow separation can obtain the pre-fractionated lubricant by molecular weight.

### EXAMPLES

One embodiment of the invention comprises a diffuser plate with circular arrays of orifices as shown in FIG. 3(a). The shutter plate has the same pattern of orifices as the diffuser plate. When a disk is present, the actuator will drive the shutter plate to rotate by such an angle that the orifices on the diffuser plate will align with those on the shutter plate. Then the lubricant will start to deposit onto the disk surfaces. After the deposition is done, the shutter plate will rotate back to block all the orifices. Then the shutter will be closed again until the next disc comes in.

Another embodiment of the invention comprises a diffuser plate with rectangular arrays of orifices as shown in FIG. 3(b). The shutter plate has the same pattern of orifices as the diffuser plate. When a disk is present, the actuator will drive the shutter plate to move linearly by such a distance that the orifices on the diffuser plate will align with those on the shutter plate. Then the lubricant will start to deposit onto the disk surfaces. After the deposition is done, the shutter plate will slide back to block all the orifices. Then the shutter will be closed again until the next disc comes in.

The method of making and using the vapor deposition chamber and the apparatus of this invention is disclosed in U.S. Pat. No. 6,183,831, which is incorporated herein in its entirety by reference.

This application discloses several numerical ranges in the text and figures. The numerical ranges disclosed inherently support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference. The implementations described above and other implementations are within the scope of the following claims.

1. An apparatus for vapor lubrication of a magnetic recording medium comprising a chamber, a diffuser plate having an array of orifices, a shutter and an actuator to move the shutter to open or close the orifices of the diffuser plate.

2. The apparatus of claim 1, further comprising a heater.

3. The apparatus of claim 1, wherein the shutter is a shutter plate.

4. The apparatus of claim 3, wherein the shutter plate comprises an array of orifices.

5. The apparatus of claim 1, wherein the array of orifices are have a circular pattern.

6. The apparatus of claim 1, wherein the array of orifices have a rectangular pattern.

7. An apparatus for vapor lubrication comprising a chamber, a diffuser plate having an array of orifices, a shutter plate having substantially the same pattern of orifices as that of the diffuser plate, a holder for holding an object to be vapor coated in the chamber, and an actuator to move the shutter plate to align the array of orifices of the shutter plate with the array of orifices of the diffuser plate or at least partially block the array of orifices of the diffuser plate with the diffuser plate.

8. The apparatus of claim 7, further comprising a heater.

9. The apparatus of claim 7, wherein the holder is for holding a magnetic recording disk.

10. The apparatus of claim 7, further comprising a lubricant reservoir.

11. The apparatus of claim 9, wherein the actuator aligns the array of orifices of the shutter plate with the array of orifices of the diffuser plate to allow a lubricant vapor to diffuse through the array of orifices of the diffuser when the magnetic recording disk in within the chamber and to at least partially blocks the array orifices of the diffuser plate with the diffuser plate when there is no magnetic recording disk in the chamber.

12. The apparatus of claim 7, wherein the array of orifices are have a circular pattern.

13. The apparatus of claim 7, wherein the array of orifices have a rectangular pattern.

14. A method of vapor lubrication comprising a inserting an object in a chamber, opening orifices of a diffuser plate to allow a lubricant vapor to diffuse through the orifices, depositing lubricant vapor on the object and closing the orifices to substantially stop the lubricant vapor to diffuse through the orifices when the object is not present in the chamber.

15. The method of claim 14, wherein the object is a magnetic recording disk.

16. The method of claim 15, further comprising an actuator.

17. The method of claim 16, further comprising a shutter plate having substantially the same pattern of orifices as that of the diffuser plate,

18. The method of claim 17, wherein the actuator aligns the array of orifices of the shutter plate with the array of orifices of the diffuser plate to allow a lubricant vapor to diffuse through the array of orifices of the diffuser when the magnetic recording disk in within the chamber and to at least partially blocks the array orifices of the diffuser plate with the diffuser plate when there is no magnetic recording disk in the chamber.

19. The method of claim 14, wherein the orifices are a circular array of orifices.

20. The apparatus of claim 14, wherein the orifices are a rectangular array of orifices.
